(19) United States
(12) Patent Application Publication
(10) Pub. No.: US 2013/0033919 A1
(43) Pub. Date: Feb. 7, 2013

(54) NONVOLATILE MEMORY SYSTEM AND PROGRAM METHOD THEREOF

(71) Applicant: Soo Gil KIM, Ichon-si (KR)

(72) Inventor: Soo Gil KIM, Ichon-si (KR)

(21) Appl. No.: 13/333,575

(22) Filed: Dec. 21, 2011

(30) Foreign Application Priority Data
Aug. 5, 2011 (KR) 10-2011-0078271

(51) Int. Cl. G11C 11/00

(52) U.S. Cl. 365/148

(57) ABSTRACT

A nonvolatile memory system and a program method thereof are provided. The nonvolatile memory system includes a nonvolatile memory cell array, an input/output (I/O) control circuit configured to control a program or read operation for the nonvolatile memory cell array; and a controller configured to store an equation representing a resistance-current (R-I) curve for resistance states of memory cells included in the nonvolatile memory cell array, apply an initial program current calculated based on the equation, calculate the equation based in on a resistance of a memory cell subjected to the initial program current, predict a reprogram current based on the equation obtained from the calculation, and control the I/O control circuit.

### CROSS-REFERENCES TO RELATED APPLICATION

The present application claims priority under 35 U.S.C. 119(a) to Korean application number 10-2011-0078271, filed on Aug. 5, 2011, in the Korean Patent Office, which is incorporated by reference in its entirety as if set forth in full.

### BACKGROUND

1. Technical Field

Exemplary embodiments of the present invention relate to a memory system, and more particularly, to a nonvolatile memory system and a program method thereof.

2. Related Art

In nonvolatile memory devices such as phase-change memory devices, flash memory devices, magnetic memory devices, etc, cost reduction and high integration based on a multi-level cell technology are desired.

Phase-change memory devices are useful in terms of scaling in dynamic random access memories (DRAMs) and reliability in flash memory devices. Further, the phase-change memory devices have nonvolatile characteristics and can support a high-speed operation and access in byte unit while ensuring reliability and durability and avoiding erasing operations. As such, the phase-change memory devices are emerging as the next generation storage class memory (SCM).

While a single level cell (SLC) method has been used, where one bit data is stored in a cell, a multi-level cell method (MLC), where multi bit data is stored in a cell, is useful to increase the integration density of a memory device.

FIGS. 1 and 2 are views illustrating resistance distributions of phase-change memory cells with the SLC method and the MLC method, respectively.

FIG. 1 illustrates a cell resistance distribution of the SLC method. A cell with a resistance lower than a reference resistance (R_ref) may be defined as logic “0” and a cell with a resistance higher than the reference resistance (R_ref) may be referred as logic “1”.

FIG. 2 illustrates a cell resistance distribution of the MLC method, for example, in the case where 2-bit data is stored in one cell.

Each memory cell may be divided into four states according to its resistance distribution and thereby, a plurality of reference resistances R_ref1, R_ref2, and R_ref3 are used.

Each memory cell has one of four states 00, 01, 10, and 11 as determined using the reference resistances R_ref1, R_ref2, and R_ref3.

When the MLC method is used, the integration density can be increased given the same cell size. However, time to program and verify (PNV) may also increase.

FIGS. 3A and 3B are views illustrating an example of a conventional PNV method.

FIGS. 3A and 3B illustrate a unidirectional current increase (decrease) method, which is an example of the PNV method.

In the unidirectional PNV method, an initial program current is set to a permissible minimum current (or maximum current) and when reprogram is to be performed according to a verify result, the reprogram is performed by progressively increasing (or decreasing) a program current from the minimum current (or the maximum current) at constant current change steps.

More specifically, as shown in FIGS. 3A and 3B, the initial program current is set to a minimum current and the program is performed (S101), and it is verified whether or not a cell resistance R is in a desired level resistance distribution (R_ref_L<R<R_ref_H) at S103.

In performing the verification step S103, when the cell resistance R is in the desired level resistance distribution, it is determined that the program is completed and thus, the cell is processed as a “PASS” cell (S105) (that is, the program operation stops).

On the other hand, when the cell resistance R is not in the desired level resistance distribution, the program is performed again by returning to step S101 after increasing the program current at S109.

The program and verify (PNV) process performed at S103 after increasing the program current at S109 when the cell resistance is not in the desired level resistance distribution may be repeated unless the PNV process is determined to have been repeated for a set maximum number of times at S107. Here, a cell with a cell resistance that does not reach the desired level resistance distribution after PNV process is repeated for the set maximum number of times is processed as a “FAIL” cell at S111.

In the unidirectional PNV method, since the PNV process is performed by progressively increasing or decreasing the program current from the minimum or maximum initial current, respectively, the overall program and verify process may take a considerable time.

FIGS. 4A and 4B are views illustrating a bidirectional PNV method, which is another example of the conventional PNV method.

In the bidirectional PNV method, an initial program current is set at an intermediate level of a permissible current range to perform a program and the program is performed at S201.

When a cell resistance R is detected to be lower than a is minimum resistance R_ref_L of a target resistance distribution at S203, a program current to perform reprogram is increased, for example, by a constant step increase current, and reprogram is performed at S205. After performing the reprogram, a determination as to whether the cell resistance is in a target resistance distribution (R_ref_L<R<R_ref_H) is made at S207. If the cell resistance is in the target resistance distribution (R_ref_L<R<R_ref_H), the cell is processed as a “PASS” cell at S209 (that is, the program operation stops). If the cell resistance is not in the target resistance distribution (R_ref_L<R<R_ref_H), a determination as to whether a number of times that the PNV process has been repeated is equal to a set maximum at S211. If the PNV process has not been repeated for a set maximum number of times at S211, the cell is reprogrammed at S205. Otherwise, the cell is processed as a “FAIL” cell at S213.

At S203, when the cell resistance R is not lower than the minimum resistance (R_ref_L) of the target resistance distribution (for example, when the cell resistance R is higher than the maximum resistance (R_ref_H) of the target resistance distribution), the program current is decreased and a reprogram is performed at S215. At S217, a determination is made as to whether the cell resistance R is in the target resistance distribution (R_ref_L<R<R_ref_H) (S217). If it is determined that the cell resistance R is in the target resistance distribution (R_ref_L<R<R_ref_H), the cell is processed as a “PASS” cell at S209.). If it is determined that the cell resistance R is not in the target resistance distribution, a determination is made as to whether the cell has been reprogrammed for a set maximum number of times at S219. If it is determined that the cell has been reprogrammed for the set maximum number of times, the cell is processed as a “FAIL” cell at S213. Otherwise, the cell is reprogrammed with a decreased current at S215.

In the bidirectional PNV method, the overall time required to program and verify may be reduced as compared with the unidirectional PNV method. However, since the bidirectional PNV method also scans a cell state by progressively increasing or decreasing the program current at constant current change steps, the PNV process may be repeated a large number of times.

In using a multi-level cell, the resistance states in each memory cell are increased in proportion to the number of bits to be stored therein. Here, regardless of whether the unidirectional or bidirectional method of performing the PNV process is used, the number of times that the PNV process may be repeated may be large and interfere with the high-speed operation of memory devices such as phase-change memory devices and decrease the reliability thereof.

### SUMMARY

According to an exemplary aspect of an exemplary embodiment, a nonvolatile memory system includes a nonvolatile memory cell array, an input/output (I/O) control circuit configured to control a program or read operation for the nonvolatile memory cell array, and a controller configured to store an equation representing a resistance-current (R-I) curve for resistance states of memory cells included in the nonvolatile memory cell array, apply an initial program current calculated based on the equation, calculate the equation based on a resistance of a memory cell subjected to the initial program current, predict a reprogram current based on the equation obtained from the calculation, and control the I/O control circuit.

According to another exemplary aspect of an exemplary embodiment, a program method of a nonvolatile memory system including a controller and a non-volatile memory cell array configured to be controlled by the controller is provided. The method includes storing an equation representing a resistance-current (R-I) curve for resistance states of memory cells included in the nonvolatile memory cell array and applying an initial program current calculated based on the equation, performing a program and verify process after the application of the initial program current, calculating the equation based on a measured resistance of a memory cell after the program and verify process when the measured resistance is not in a target resistance distribution, predicting a program current corresponding to a target program resistance based on the equation after the calculation of the equation, and performing a reprogram and verify process using the predicted program current.

These and other features, aspects, and embodiments are described below in the section entitled “DESCRIPTION OF EXEMPLARY EMBODIMENT”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIGS. 1 and 2 are views illustrating resistance distributions of a cell in a single level cell (SLC) method and a multi level cell (MLC) method;

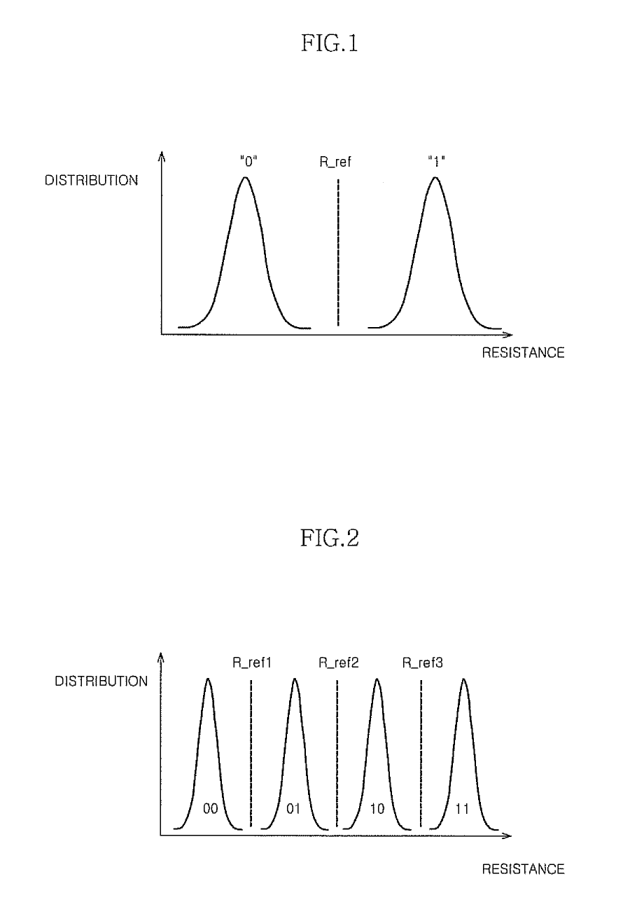

FIGS. 3A and 3B are views illustrating an example of a conventional PNV method;

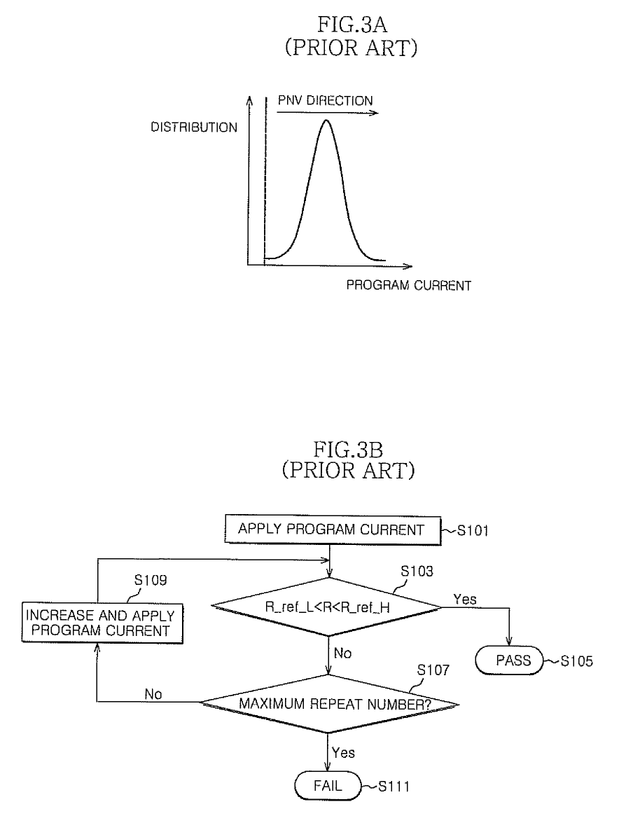

FIGS. 4A and 4B are views illustrating another example of a conventional PNV method;

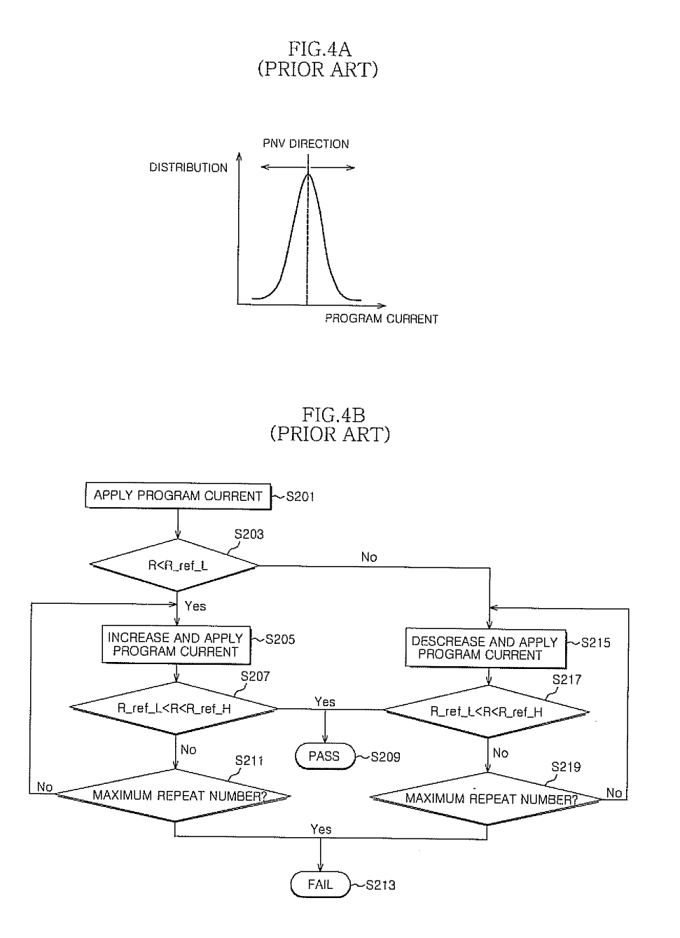

FIG. 5 is a view illustrating a configuration of a nonvolatile memory system according to an exemplary embodiment;

FIG. 6 is an illustrative diagram of a resistance-current (R-I) curve applied to the exemplary embodiment;

FIGS. 7 and 8 are flowcharts illustrating program methods of a nonvolatile memory system according to exemplary embodiments;

FIGS. 9A to 9E are views illustrating a program efficiency according to a PNV method; and

FIG. 10 is a view illustrating comparison of an average repeat number of PNV for each PNV method.

### DESCRIPTION OF EXEMPLARY EMBODIMENT

While the present invention is susceptible to various modifications and alternative forms, specific embodiments thereof are shown by way of example in the drawings and will be described in detail.

It should be understood, however, the present invention are not limited to the particular forms disclosed and extend to all modifications, equivalents, and alternatives reasonably suitable for implementing the present invention.

The terminology used herein is for the purpose of describing particular embodiments only and is not intended to be limiting. As used herein, the singular forms are intended to include the plural forms as well, unless the context clearly indicates otherwise. It will be further understood that the terms “comprises”, “comprising,” “includes,” and/or “including,” when used herein, specify the presence of the stated features, integers, steps, operations, elements, and/or components, and do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the related art and the present disclosure and will not be interpreted in an idealized, strict context unless expressly stated herein.

Hereinafter, exemplary embodiments of the present invention will be more specifically described with reference to the accompanying drawings.

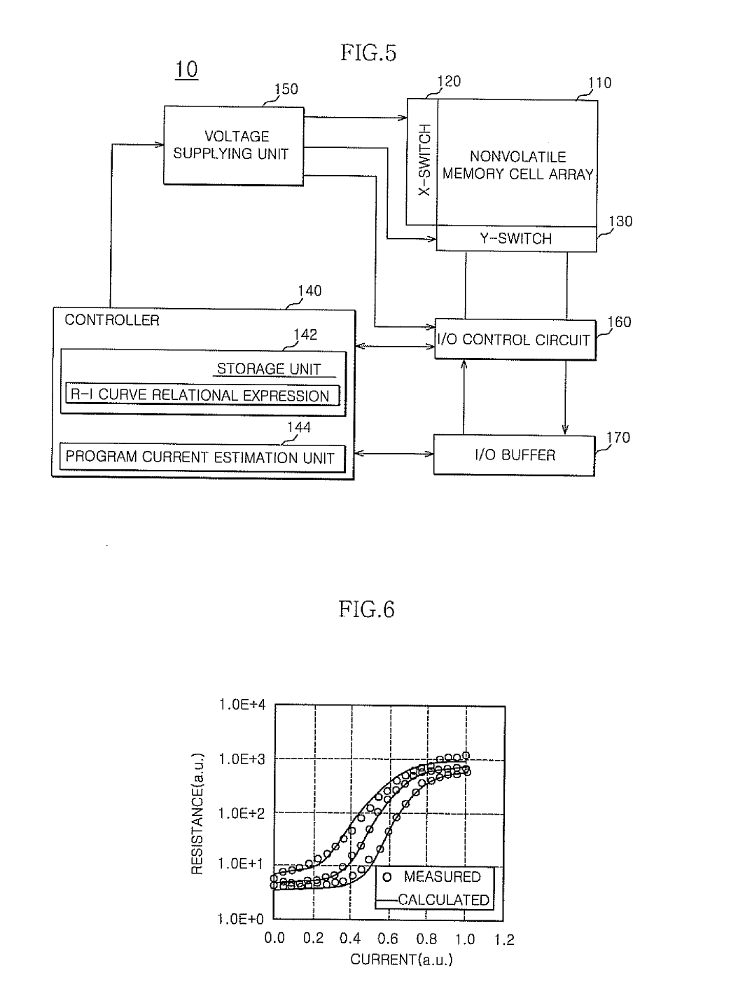

FIG. 5 is a diagram of a nonvolatile memory system according to an exemplary embodiment.

Referring to FIG. 5, the nonvolatile memory system 10 includes a memory cell array 110, an X-switch 120 configured to select a word line, an Y-switch 130 configured to select a bit line, a controller 140 configured to control an overall operation, a voltage supplying unit 150, an input/output (I/O) control circuit 160, and an I/O buffer 170.

The memory cell array 110 may include a plurality of memory cells and each memory cell may store N-bit data, where N is a natural number. Further, when a unit memory cell of the memory cell array 110 is a phase-change memory cell, each memory cell may include a switching device and a resistive device operating as a data storage.

The X-switch 120 selects at least one of a plurality of word lines in response to a row address and the Y-switch 130 selects at least one of a plurality of bit lines in response to a column address, where the generation of row address and column address is controlled by the controller 140.

The controller 140 controls an overall operation of the nonvolatile memory system in response to a command received externally (for example, from a host). The voltage supplying unit 150 is controlled by the controller 140 and supplies internal voltages for operating peripheral circuits such as the X-switch 120 and the Y-switch 130.

The I/O control circuit 160 may include a write driver and a sense amplifier.

The I/O buffer 170 temporarily stores data input externally in response to control signals from the controller 140 during a program operation, where the temporarily stored data is stored in the memory cell array 110 through the I/O control circuit 160. Further, when data stored in the memory cell array 110 is read through the I/O control circuit 160 during a read operation controlled by the controller 140, the I/O buffer 170 provides the read data to the controller 140.

Here, according to an example, the controller 140 includes a storage unit 142 and a program current prediction unit 144.

The storage unit 142 stores a resistance-current (R-I) relational expression that expresses measured resistance and program current of memory cells included in the memory cell array 110 as points on an R-I curve. In deriving the R-I relational expression for being stored in the storage unit 142, the resistance values and current values may be detected from memory cells of the memory cell array 110 or from designated sample cells.

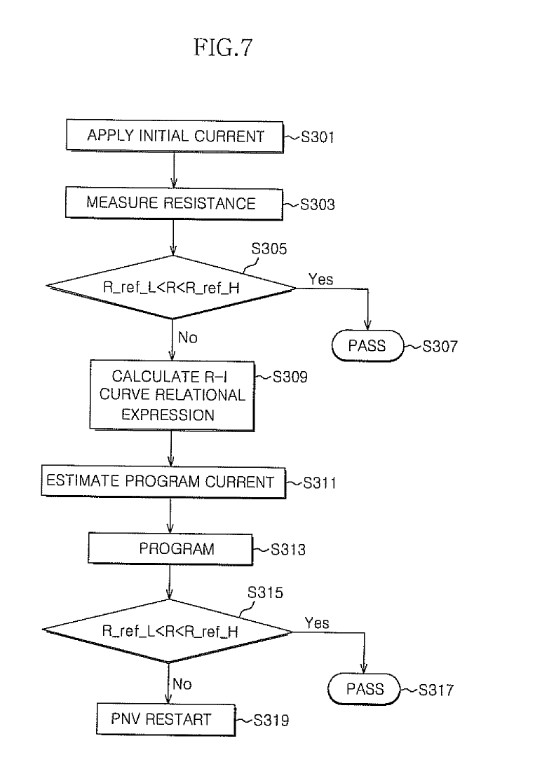

FIG. 6 is an illustrative diagram of an R-I curve according to an example.

FIG. 6 illustrates R-I curves obtained from measured resistance and current from three-types of memory cells included in the memory cell array 110 and R-I curves obtained from an equation expressing the relationship between the measured resistance and current.

When an R-I curve is obtained based on the measured resistance and current, for example, the following equation may be obtained to express their correspondence.

$$R ∝ exp ( - exp ( - \frac{I - A}{B} ) - \frac{I - A}{B} + 1 ) + C exp ( D \times I ) \qquad ( Equation 1 )$$

where A, C, and D are constants, B is a variable, I is current, and R is resistance. The constants A, C, and D are determined according to characteristics of a wafer on which memory cells are manufactured and may be determined during tests and stored in the storage unit 142. The variable B is used in estimating a program current to be applied to a memory cell in program and will be described later in detail. Here while constants A, C, and D are not changed in the Equation 1 once they are set during tests, variable B is changed in determining reprogram current I.

Equation I which expresses an R-I curve of a nonvolatile memory cell (for example, a phase-change memory cell) is exemplary only and other equations may be used to express an R-I curve of a nonvolatile memory cell.

The controller 140 provides a program command, data, an address and an initial program current to the I/O control circuit 160 for programming. An initial program current may be determined by selecting any one current value of a desired current range that changes a resistance state of a memory cell according to an R-I curve of a nonvolatile memory cell. For example, referring to FIG. 6, the initial program current may be selected to be a current value within a current range that a phase-change memory cell is phase-changeable (e.g., a range between 0.3 mA and 0.8 mA). Here, the variable B is set to have a set initial value during the initial program operation for applying the initial program current, where the variable B may be changed during reprogram operations as described below.

When the program is performed by applying the initial program current and resistance of the memory cell is determined during a subsequent verification, the controller 140 processes the memory cell as a “PASS” cell or controls a reprogram of the memory cell depending on whether the read resistance is within the desired resistance distribution.

When the reprogram is to be performed, the controller 140 uses an R-I curve function which reflects a resistance state of a corresponding memory cell and is stored in the storage unit 142.

The program current estimation unit 144 of the controller 140 acquires a current corresponding to a target resistance on a corresponding R-I curve function and selects the acquired current as the program current to perform the reprogram. The controller 140 checks whether the detected resistance of the memory cell during a subsequent verification is within the desired resistance distribution and determines to process the memory cell as a “PASS” cell or to reprogram.

In other words, the controller 140 determines to process a memory cell as a “PASS” cell or to reprogram based the detected resistance of the memory cell after performing a program with the initial program current. When a reprogram is to be performed, the controller 140 estimates a reprogram current corresponding to the target resistance by using a revised R-I curve function. The revised R-I curve function is obtained by using variable B calculated based on the R-I curve function and by inputting the measured resistance and current. After the reprogram is performed by using the revised R-I curve function with the changed variable B and by using the estimated current based on the revised R-I curve as the reprogram current, a verification of the program is performed by detecting the resistance of the memory cell.

The R-I distribution of each memory cell may have any one of the curves shown in FIG. 6, where the reprogram current corresponding to the target resistance may be estimated from the R-I curve function corresponding to the resistance read from the initial program current. Therefore, when the reprogram is performed using the estimated reprogram current, the resistance of a corresponding memory cell may be changed to be within the desired resistance distribution.

On the other hand, the resistance of the memory cell may not be within the desired resistance distribution after the reprogram and verification. In this case, the PNV process is restarted, where the bidirectional PNV method as described above may be used.

The program and verify (PNV) method according to control of the above-described controller 140 will be described with reference to flowcharts.

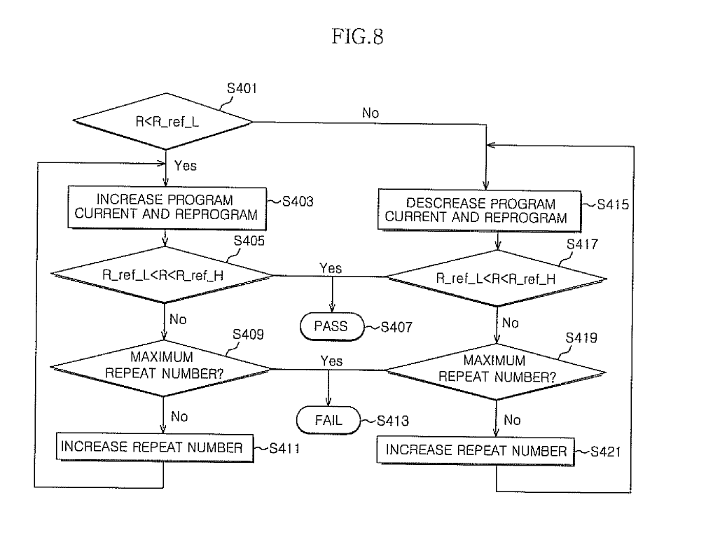

FIGS. 7 and 8 are flowcharts illustrating program methods of a nonvolatile memory system according to exemplary embodiments.

First, referring to FIG. 7, the controller 140 provides a program command, data, an address, and a set initial program current to the I/O control circuit 160 to cause an initial program to be performed (S301).

Thereby, the I/O control circuit 160 applies an initial program current to a corresponding memory cell to perform the program, reads a resistance changed by the program, and provides the read resistance to the controller 140 at S303.

The controller 140 checks whether or not the read cell resistance R is within the desired resistance distribution (R_ref_L<R<R_ref_H) at S305 and when the cell resistance R, which is changed in response to the initial program current, is in the desired resistance distribution, the controller 140 processes the memory cell as a “PASS” cell at S307.

On the other hand, when the cell resistance R is not in the desired resistance distribution, since a reprogram is to be performed, the controller 140 calculates an R-I curve function representing the R-I curve of the cell by using the representative R-I function stored in the storage unit 142 and the read cell resistance R at S309. Based on the calculated R-I curve function, the controller 140 determines a current matched to the target resistance and estimates a reprogram current at S311.

A process of calculating the R-I curve function and estimating the reprogram current to be used in a reprogram will be described in more detail.

For example, when the R-I curve function is the above-described Equation 1, the read cell resistance R, the initial program current I, the constants A, C, and D are substituted in Equation 1 to calculate the variable B. Here, an R-I curve function which reflects the R-I characteristic of a corresponding memory cell may be determined.

When the R-I curve function is calculated, a current corresponding to the target resistance may be estimated based on the calculated/reformulated R-I curve relational expression.

The controller 140 applies the estimated reprogram current again to perform the reprogram at S313 and checks whether the detected cell resistance R is within the target distribution (R_ref_L<L<R_ref_H) during a program verification at S315 and, based on the program verification, processes the memory cell as a “PASS” cell at S317 or perform the PNV process again at S319.

When the PNV process is to be performed again at S319, according to an example, the bidirectional PNV method may be used, where such steps are described in detail as follows with reference to FIG. 8.

At S401, the controller 140 checks whether the cell resistance R measured after the reprogram at S313 of FIG. 7 is below or above the target resistance distribution.

If the read cell resistance R is determined to be lower than the minimum resistance R_ref_L of the target resistance distribution at S401, the controller 140 increases the program current from, for example, the previous program current level by a step increase current, and performs a reprogram at S403. After the reprogram, the controller 140 determines whether the cell resistance R is between the target resistance distributions (R_ref_L<R<R_ref_H) at S405). Based on the determination at S405, the controller 140 processes the memory cell as a “PASS” cell at S407) or determines whether the PNV process has been repeated for a maximum number of times at S409. Based on the determination at S409, the controller 140 increases a number indicating the number of times that the PNV process has been repeated by one at S411 and goes back to S403 for another reprogram or processes the memory cell as a “FAIL” cell at S413.

At S401, when the cell resistance R is determined to be higher than the maximum resistance (R_ref_H) of the target resistance distribution, the controller 140 decreases the program current to perform reprogram from, for example, the previously applied program current level, at S415. The controller 140 determines whether the cell resistance R is within the target resistance distributions (R_ref_L<R<R_ref_H) at S417. Based on the determination at S417, the controller 140 processes the memory cell as a “PASS” cell at S407 or determines whether the PNV process has been repeated for a maximum set number of times at S419. Based on the determination at S419, the controller 140 increases a number indicating the number of times that the PNV process has been repeated by one at S419 S411 and goes back to S415 for another reprogram or processes the memory cell as a “FAIL” cell at S413.

According to an exemplary embodiment of the present invention, the R-I curve function is calculated based on the detected R-I state of the cell by measuring the resistance R of the cell in response to the initial program current and estimates a program current within the desired resistance distribution using the calculated R-I curve function. Therefore, the number of times that the PNV is repeated can be minimized/reduced to thus reduce the overall time for programming.

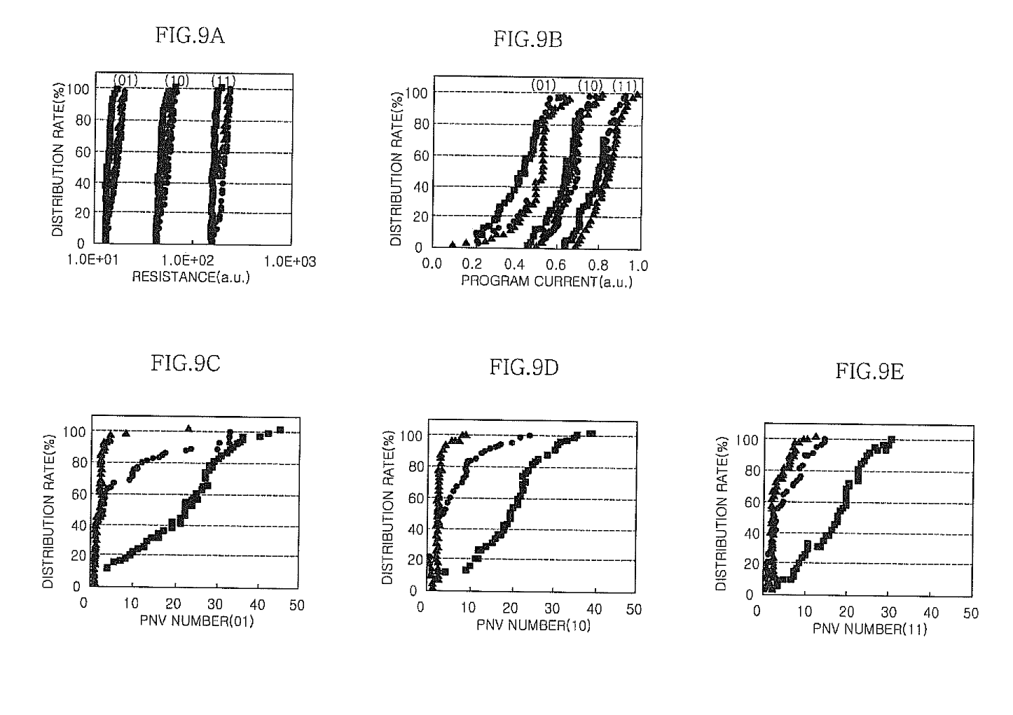

FIGS. 9A to 9E are views illustrating a program efficiency according to different PNV methods.

First, FIG. 9A illustrates resistance distributions, that is, a resistance distribution (▪) by the conventional unidirectional PNV method, a resistance distribution (•) by the conventional bidirectional PNV method, and a resistance distribution (▴) by the PNV method according to an exemplary embodiment of the present invention.

In the MLC method memory cell which stores 2-bit data 00, 01, 10, and 11, the resistance distribution is uniform while a number of times a memory cell is reprogrammed is reduced according to an exemplary embodiment of the present invention. Thus, the resulting resistance distributions in FIG. 9A show that the program operation according to an exemplary embodiment of the present invention is reliable.

FIG. 9B is illustrates a final PNV current range.

In the case where the PNV method according to an exemplary embodiment of the present invention is applied, where data points are indicated by (▴), each data can be accurately recorded without a large variation in the program current.

FIGS. 9C to 9E are respective graphs showing the comparison of the numbers that the PNV process are repeated to program 01, 10, and 11.

It is seen that in the case of the conventional unidirectional PNV method, which data points are indicated by (▪), the PNV process is repeated for a large number of times to achieve a particular distribution rate indicating a rate of memory cells within a desired resistance distribution and in the case of the conventional bidirectional PNV method solely, which data points are indicated by (•), the PNV process is repeated for a smaller number of times than using the unidirectional PNV method only. However, in the case of the PNV method according to an exemplary embodiment of the present invention, which data points are indicated by (▴), the PNV process is repeated for even smaller number of times.

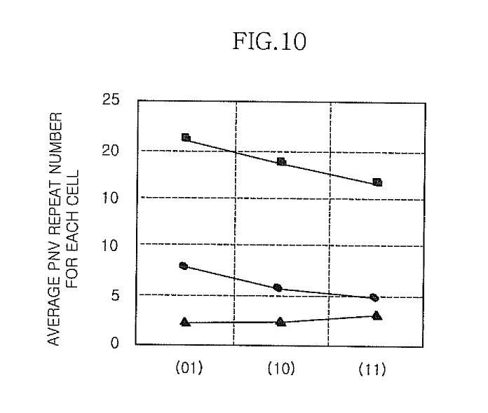

FIG. 10 is a view illustrating the comparison of the average number of times that the PNV is repeated for different PNV methods.

In the case of solely using the conventional unidirectional PNV method having data points (▪), the average number that the PNV process is repeated is 15 or more in programming different data.

In the case of solely using the conventional bidirectional PNV method having data points (•), the average number that the PNV process is repeated is smaller than in comparison to the conventional unidirectional PNV method, but the PNV process is repeated 5 times or more for each cell.

In the case of using the PNV method (▴) according to an exemplary embodiment of the present invention, the PNV process for programming different data (that is, programming data by changing resistance of memory cells to be within desired resistance ranges) is equal to or less than 5, and thus the program speed is increased.

[Table 1] shows the total number of times that the PNV have been repeated for programming 71 cells in experiments performed according to different PNV methods for different data.

TABLE 1

| | 01 | 10 | 11 |
|---|---|---|---|
| Unidirectional PNV Only | 1489 | 1346 | 1196 |
| Bidirectional PNV Only | 554 | 421 | 350 |
| PNV according to an | 178 | 179 | 236 |
| exemplary | | | |
| embodiment | | | |

[Table 2] shows the average number of times that PNV have been repeated for a cell according to different PNV methods.

TABLE 2

| | 01 | 10 | 11 |
|---|---|---|---|
| Unidirectional PNV Only | 21.1 | 19.0 | 16.8 |
| Bidirectional PNV Only | 7.8 | 5.9 | 4.9 |
| PNV according to an | 2.1 | 2.5 | 3.3 |
| exemplary | | | |
| embodiment | | | |

When the PNV method according to an exemplary embodiment of the present invention is applied, the total and average number of PNV repetition may be reduced.

According to an exemplary embodiment of the present invention, the desired resistance dispersion can be formed with, for example, 10 to 20% of the number of PNV repetition using the conventional unidirectional PNV method or about at 25 to 60% of the number of PNV repetition using the conventional bidirectional PNV method.

According to an exemplary embodiment of the present invention, the average number of PNV repetition may be two or three times, where such a low number indicates that the process of deriving the R-I curve function based on the measured resistance and estimating the program current using the derived function is accurately performed and additional PNV scanning process may be avoided. Accordingly, when the PNV method according to an exemplary embodiment of the present invention is applied, a high speed of the nonvolatile memory device may be obtained and reliability of the nonvolatile memory device may be improved.

While the exemplary embodiments of the present invention have been mostly described using a phase-change memory device as an example, the exemplary embodiments of the present invention are not limited thereto and may be applied to different types of nonvolatile memory devices capable of performing a program operation through a program and verification process.

According to an exemplary embodiment of the present invention, an R-I curve function representing an R-I curve of a nonvolatile memory cell is stored in a database and the function representing the R-I curve of each cell is derived again by applying an initial program current to the selected memory cell and measuring a resistance thereof. Then, a program current is estimated to have a desired resistance using the recalculated function and the program is performed.

Here, the memory cell may be changed to a desired resistance state by applying the estimated program current without necessarily increasing or decreasing a program in constant incremental steps.

According to an exemplary embodiment of the present invention, the high-speed and reliability of the nonvolatile memory system and more stable operation thereof may be obtained.

While particular exemplary embodiments have been described above, they are exemplary only and the present invention should not be limited to any specific disclosed embodiment.

What is claimed is:

1. A nonvolatile memory system, comprising:
a nonvolatile memory cell array;
an input/output (I/O) control circuit configured to control a program or read operation for the nonvolatile memory cell array; and
a controller configured to store an equation representing a resistance-current (R-I) curve for resistance states of memory cells included in the nonvolatile memory cell array, apply an initial program current calculated based on the equation, calculate the equation based on a resistance of a memory cell subjected to the initial program current, predict a reprogram current based on the equation obtained from the calculation, and control the I/O control circuit.

2. The nonvolatile memory system of claim 1, wherein the controller includes:
a storage configured to store the equation; and
a current prediction unit configured to apply the initial program current to the I/O control circuit, receive a measurement of a resistance after the application of the initial program current, calculate the equation based on the measured resistance, and predict a reprogram current corresponding to a target program resistance based on the equation obtained from the calculation.

3. The nonvolatile memory system of claim 1, wherein the controller is configured to perform a reprogram and verify process when a resistance of the memory cell is not within a target resistance distribution by using the reprogram current.

4. The nonvolatile memory system of claim 3, wherein the reprogram and verify process includes a bidirectional program and verify process.

5. The nonvolatile memory system of claim 1, wherein the controller is configured to stop a program operation of the memory cell when the measured resistance of the memory cell is within a target resistance distribution.

6. The nonvolatile memory system of claim 1, wherein the controller is configured to store an initial value of a variable in the equation and change the stored value of the variable based on the resistance of the memory cell subjected to the initial program current and based on the initial program current.

7. The nonvolatile memory system of claim 1, wherein when the resistance of the memory cell is not within a target resistance distribution after being applied with the reprogram current, the controller is configured to perform a reprogram and verify process by selecting to repeatedly change a program current by a step current change, apply the repeatedly changed program current to the memory cell, and verify the resistance of the memory cell after each application of the repeatedly changed program current until the resistance of the memory cell is within the target resistance distribution.

8. A program method of a nonvolatile memory system including a controller and a non-volatile memory cell array configured to be controlled by the controller, the method comprising:
storing an equation representing a resistance-current (R-I) curve for resistance states of memory cells included in the nonvolatile memory cell array and applying an initial program current calculated based on the equation;
performing a program and verify process after the application of the initial program current;
calculating the equation based on a measured resistance of a memory cell after the program and verify process when the measured resistance is not in a target resistance distribution;
predicting a program current corresponding to a target program resistance based on the equation after the calculation of the equation; and
performing a reprogram and verify process using the predicted program current.

9. The program method of claim 8, further comprising stopping a program operation of the memory cell when the measured resistance of the memory cell is within a target resistance distribution.

10. The program method of claim 8, wherein the reprogram and verify process is performed when the measured resistance of the memory cell is not within the target resistance distribution.

11. The program method of claim 10, further including performing, when the measured resistance of the memory cell is not within the target resistance distribution after being applied with the reprogram current, performing an additional reprogram and verify process by selecting to repeatedly change a program current by a step current change, applying the repeatedly changed program current to the memory cell, and verifying the measured resistance after each application of the repeatedly changed program current until the measured resistance is within the target resistance distribution.
